(19) United States
(12) Patent Application Publication
(10) Pub. No.: US 2026/0140147 A1
(43) Pub. Date: May 21, 2026

(54) HIGH-BANDWIDTH CURRENT-sensing EXTRACTION- COIL SENSOR

(71) Applicants: Xidian University, Xi’an (CN); Guangzhou Institute of Technoloy, Xidian University, Guangzhou (CN)

(72) Inventors: Shuzhen You, Guangzhou (CN); Haonan Jiang, Xi’an (CN); Longyang Yu, Xi’an (CN); Jincheng Zhang, Xi’an (CN); Yue Hao, Xi’an (CN)

(21) Appl. No.: 19/332,421

(22) Filed: Sep. 18, 2025

(30) Foreign Application Priority Data
Nov. 21, 2024 (CN) 2024116747441

(51) Int. Cl. G01R 15/18; G01R 22/08; H01F 5/00; H01F 27/40

(52) U.S. Cl. CPC G01R 15/181; G01R 22/08; H01F 5/003; H01F 27/402

(57) ABSTRACT

A high-bandwidth current-sensing extraction-coil sensor is provided. The sensor includes: a single-turn current extraction coil used to generate a voltage based on an input current by using Faraday's law, and the single-turn current extraction coil includes single-turn copper coils; a coil terminal matching resistor R_{d}, connected to the single-turn current extraction coil and used to perform impedance matching on the voltage to produce a matched voltage signal; and a signal processing circuit, individually connected to the single-turn current extraction coil and the coil terminal matching resistor R_{d} and used to restore the matched voltage signal and output a restored current to achieve current detection. The single-turn copper coils are employed to reduce parasitic capacitance and parasitic inductance, thereby increasing current detection bandwidth and avoiding introduction of parasitic inductance interference when measuring fast GaN devices. The sensor is adopted to achieve a lower manufacturing cost.

### CROSS-REFERENCE TO RELATED APPLICATION

This application claims priority to Chinese patent application No. CN202411674744.1, filed to China National Intellectual Property Administration (CNIPA) on Nov. 21, 2024, which is herein incorporated by reference in its entirety.

### TECHNICAL FIELD

The disclosure relates to the technical field of current measurement for wide bandgap semiconductor devices, and more particularly to a high-bandwidth current-sensing extraction-coil sensor.

### BACKGROUND

Gallium nitride (GaN) devices are suitable for high-frequency power converters due to their excellent switching performance. To fully exploit the potential of the GaN devices, it is essential to investigate their switching characteristics. Switching current is a fundamental parameter for evaluating switching performance and validating the GaN devices. However, measuring the switching current of fast GaN devices poses significant challenges. The fast GaN devices exhibit extremely high switching speeds owing to their low capacitance and minimal parasitic inductance. The edge time t, of fast GaN devices may be less than 1 nanosecond (ns). According to the expression for measurement bandwidth

$$B W = \frac{0.35}{{t}_{r}} ,$$

a bandwidth of at least 350 megahertz (MHz) is required for accurate measurements. Additionally, due to their fast switching speed, narrow threshold voltage safety margin, and parasitic sensitivity, current measurements the fast GaN devices are required to be measured under conditions that are satisfied by high bandwidth and by not introducing excessive parasitic inductance into a power converter loop.

Currently, for current detection of the fast GaN devices, a Rogowski coil current sensor is employed, which is composed of a coil and an integrator. The coil is typically fabricated in a circular helical structure and is characterized by advantages such as being minimally affected by a position of an internal current-carrying conductor and being free from magnetic saturation issues. In order to improve the sensitivity and accuracy of the Rogowski coil current sensor, multi-turn coils are generally adopted. However, multi-turn coils are associated with larger inserted parasitic inductance and parasitic capacitance, which limit the measurement bandwidth, resulting in a lower bandwidth, and causing interference from inserted parasitic inductance during current measurement of the fast GaN devices. A commonly used Rogowski coil model, such as the TRCP0600, is relatively expensive, leading to higher manufacturing costs for such sensors.

### SUMMARY

An objective of embodiments of the disclosure is to provide a high-bandwidth current-sensing extraction-coil sensor to solve problems of low bandwidth of a Rogowski coil current sensor, insertion of parasitic inductance interference when measuring a current on a fast GaN device, and high manufacturing cost of the Rogowski coil current sensor.

To solve the above technical problems, the embodiments of the disclosure provide the following technical solutions.

Specifically, the disclosure provides a high-bandwidth current-sensing detection extraction-coil sensor, including a single-turn current extraction coil, a coil terminal matching resistor R_{d} and a signal processing circuit.

The single-turn current extraction coil is used to generate a voltage based on an input current by using Faraday's law and the single-turn current extraction coil includes single-turn copper coils.

The coil terminal matching resistor R_{d} is connected to the single-turn current extraction coil and is configured to perform impedance matching on the voltage to generate a matched voltage signal.

The signal processing circuit is connected to the single-turn current extraction coil and the coil terminal matching resistor R_{d} individually, and is configured to restore the matched voltage signal and output a restored current to realize current detection.

In some embodiments, the high bandwidth current-sensing extraction-coil sensor further includes an output current terminal, a measurement port Vₒᵤₜ₁ and a measurement port Vₒᵤₜ₂.

The output current terminal is connected to the signal processing circuit and the measurement port Vₒᵤₜ₂ respectively, and is configured to output the restored current.

The measurement port Vₒᵤₜ₁ is connected to the single-turn current extraction coil, the coil terminal matching resistor R_{d}, and the signal processing circuit individually, and is configured to perform frequency scanning on the single-turn current extraction coil to obtain a bandwidth of the single-turn current extraction coil.

The measurement port Vₒᵤₜ₂ is connected to the signal processing circuit and is configured to perform frequency scanning on the high-bandwidth current-sensing extraction-coil sensor to obtain a bandwidth of the high-bandwidth current-sensing extraction-coil sensor.

In some embodiments, the signal processing circuit includes a passive resistor-capacitor (RC) integrator, a resistor R₁ and an active integrator.

A non-inverting input of the voltage follower is individually connected to an end of the coil terminal matching resistor R_{d}, an end of the measurement port Vₒᵤₜ₁, and the single-turn current extraction coil; an inverting input of the voltage follower is connected to the passive RC integrator; an output terminal of the voltage follower is connected to the passive RC integrator; and the voltage follower is configured to follow the matched voltage signal and output a followed voltage signal.

The passive RC integrator is individually connected to an end of the resistor R₁, the other end of the coil terminal matching resistor R_{d}, the other end of the measurement port Vₒᵤₜ₁, the single-turn current extraction coil, and the active integrator; and is configured to filter and integrate the following voltage signal sequentially, and output an integrated current signal.

The active integrator is individually connected to the other end of the resistor R₁, the measurement port Vₒᵤₜ₂, and the output current terminal, and is configured to restore the integrated current signal and output the restored current to realize the current detection.

The end of the resistor R₁ is individually connected to the other end of the measurement port Vₒᵤₜ₁, the other end of the coil terminal matching resistor R_{d}, and the single-turn current extraction coil.

In some embodiments, the passive RC integrator includes a resistor R₀ and a capacitor C₀.

An end of the resistor R₀ is individually connected to the output terminal of the voltage follower and the inverting input of the voltage follower; the other end of the resistor R₀ is connected to an end of the capacitor C₀ and the active integrator; the end of the capacitor C₀ is connected to the active integrator; and the other end of the capacitor C₀ is individually connected to the end of the resistor R₁, the other end of the coil terminal matching resistor R_{d}, the other end of the measurement port Vₒᵤₜ₁, and the single-turn current extraction coil.

In some embodiments, the active integrator includes an operational amplifier, a resistor R₂ and a capacitor C₁.

A non-inverting input of the operational amplifier is individually connected to the other end of the resistor R₀ and the end of the capacitor C₀; an inverting input of the operational amplifier is individually connected to the other end of the resistor R₁, an end of the resistor R₂, and an end of the capacitor C₁; an output terminal of the operational amplifier is individually connected to the other end of the resistor R₂, the other end of the capacitor C₁, an end of the measurement port Vₒᵤₜ₂, and the output current terminal; the end of the resistor R₂ is individually connected to the end of the capacitor C₁ and the other end of the resistor R₁; the other end of the resistor R₂ is respectively connected to the other end of the capacitor C₁, the output current terminal, and the end of the measurement port Vₒᵤₜ₂; the end of the capacitor C₁ is connected to the other end of the resistor R₁; and the other end of the capacitor C₁ is connected to the output current terminal and the end of the measurement port Vₒᵤₜ₂.

In some embodiments, the signal processing circuit further includes a resistor R₃.

An end of the resistor R₃ is connected to the inverting input of the voltage follower, and the other end of the resistor R₃ is individually connected to the output terminal of the voltage follower and the end of the resistor R₀.

In some embodiments, an equivalent circuit of the single-turn current extraction coil includes a mutual inductor Mₛ, a resistor Rₛ, a parasitic inductor L_{S} and a capacitor Cₛ arranged between the single-turn current extraction coil and a current-carrying conductor to be measured.

An end of the mutual inductor Mₛ is connected to an end of the resistor Rₛ, and the other end of the mutual inductor Mₛ is individually connected to an end of the capacitor Cₛ, the other end of the coil terminal matching resistor R_{d}, the other end of the measurement port Vₒᵤₜ₁, the other end of the capacitor C₀, and the end of the resistor R₁.

The other end of the resistor Rₛ is connected to an end of the parasitic inductor L_{S}, and the other end of the parasitic inductor L_{S} is respectively connected to the other end of the capacitor Cₛ, the end of the coil terminal matching resistor R_{d}, the end of the measurement port Vₒᵤₜ₁, and the non-inverting input of the voltage follower, the other end of the capacitor Cₛ is individually connected to the end of the coil terminal matching resistor R_{d}, the end of the measurement port Vₒᵤₜ₁, and the non-inverting input of the voltage follower, and the end of the capacitor Cₛ is individually connected to the other end of the coil terminal matching resistor R_{d}, the other end of the measurement port Vₒᵤₜ₁, the other end of the capacitor C₀, and the end of the resistor R₁.

In some embodiments, a negative power supply terminal of the voltage follower is connected to ground.

In some embodiments, the end of the measurement port Vₒᵤₜ₂ and a negative power supply terminal of the operational amplifier are both connected to ground.

In some embodiments, a forward output terminal of the single-turn current extraction coil is connected to a current inflow terminal of a current-carrying conductor to be measured, and a negative output terminal of the single-turn current extraction coil is connected to a current output terminal of the current-carrying conductor to be measured.

Compared with the related art, the disclosure provides the high-bandwidth current-sensing extraction-coil sensor, including the single-turn current extraction coil, the coil terminal matching resistor R_{d} and the signal processing circuit. The single-turn current extraction coil is used to generate the voltage based on the varying input current by using the Faraday's law, and the single-turn current extraction coil includes single-turn copper coils. The coil terminal matching resistor R_{d} is connected to the single-turn current extraction coil and is used to perform impedance matching on the voltage to produce the matched voltage signal. The signal processing circuit is individually connected to the single-turn current extraction coil and the coil terminal matching resistor R_{d} and is used to restore the matched voltage signal and output the restored current to achieve the current detection. In this situation, the single-turn copper coils of the single-turn current extraction coil are used to reduce parasitic capacitance and parasitic inductance, thereby increasing current detection bandwidth and avoiding introduction of parasitic inductance interference when measuring fast GaN devices. The single-turn current extraction coil, the coil terminal matching resistor R_{d} and the signal processing circuit are low in price, so that the manufacturing cost of the high-bandwidth current-sensing extraction-coil sensor is low.

### BRIEF DESCRIPTION OF DRAWINGS

The above and other objectives, features, and advantages of the disclosure will become more readily apparent from the following detailed description, read in conjunction with the accompanying drawings. In the accompanying drawings, several embodiments of the disclosure are shown by way of example and not limitation, with identical or corresponding reference numerals indicating identical or corresponding parts.

FIG. 1 illustrates a schematic structural diagram of a high-bandwidth current-sensing extraction-coil sensor.

FIG. 2 illustrates a first schematic equivalent circuit diagram of the high-bandwidth current-sensing extraction-coil sensor.

FIG. 3 illustrates a second schematic equivalent circuit diagram of the high-bandwidth current-sensing extraction-coil sensor.

FIG. 4 illustrates a schematic equivalent circuit diagram of a single-turn current extraction coil.

FIG. 5 illustrates a third schematic equivalent circuit diagram of the high-bandwidth current-sensing extraction-coil sensor.

FIG. 6 illustrates a schematic structural diagram of the single-turn current extraction coil.

FIG. 7 illustrates a schematic theoretical analysis diagram of amplitude-frequency and phase-frequency response of the single-turn current extraction coil.

FIG. 8 illustrates a schematic theoretical analysis diagram of amplitude-frequency and phase-frequency response of the high-bandwidth current-sensing extraction-coil sensor.

FIG. 9 illustrates a schematic simulation analysis diagram of the amplitude-frequency and phase-frequency response of the single-turn current extraction coil.

FIG. 10 illustrates a schematic simulation analysis diagram of the amplitude-frequency and phase-frequency response of the high-bandwidth current-sensing extraction-coil sensor.

### DETAILED DESCRIPTION OF EMBODIMENTS

Implementation of the disclosure is further described in detail below with reference to the accompanying drawings and embodiments. Detailed descriptions of the following embodiments and the drawings are used to exemplarily illustrate principles of the disclosure, but cannot be used to limit the scope of the disclosure. The disclosure can be implemented in many different forms and is not limited to the specific embodiments disclosed in the disclosure, but includes all technical solutions falling within the scope of the claims.

An embodiment of a high-bandwidth current-sensing extraction-coil sensor according to the disclosure is described in detail below.

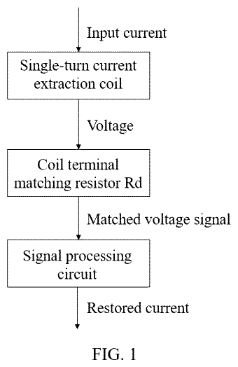

Referring to FIG. 1, FIG. 1 illustrates a schematic structural diagram of the high-bandwidth current-sensing extraction-coil sensor. In this embodiment, the high-bandwidth current-sensing extraction-coil sensor is proposed, which includes a single-turn current extraction coil, a coil terminal matching resistor R_{d}, and a signal processing circuit.

The single-turn current extraction coil is used to generate a voltage based on an input current by using Faraday's law. The single-turn current extraction coil includes single-turn copper coils.

The coil terminal matching resistor R_{d} is connected to the single-turn current extraction coil and is used to perform impedance matching on the voltage to generate a matched voltage signal.

The signal processing circuit is connected to the single-turn current extraction coil and the coil terminal matching resistor R_{d} individually, and is used to restore the matched voltage signal and output a restored current to realize current detection.

In this embodiment, a forward output terminal of the single-turn current extraction coil is connected to a current input terminal of a current-carrying conductor to be measured, and a reverse output terminal of the single-turn current extraction coil is connected to a current output terminal of the current-carrying conductor to be measured.

Specifically, before conducting current detection using the high-bandwidth current-sensing extraction-coil sensor, the single-turn current extraction coil within the sensor is placed above (or below) the current-carrying conductor to be measured. According to Faraday's law, a voltage (out+ and out−) is induced by the varying current, so that current detection can be performed using the connected high-bandwidth current-sensing extraction-coil sensor. This high-bandwidth current-sensing extraction-coil sensor is placed on the surface of the current-carrying conductor to be measured. This arrangement ensures that the parasitic inductance is zero during current detection, thereby avoiding the interference of the insertion inductance.

The single-turn current extraction coil, implemented as the single-turn copper coils, is adopted to reduce parasitic capacitance and parasitic inductance, thereby increasing the bandwidth of current detection.

The high-bandwidth current-sensing extraction-coil sensor of the disclosure is designed based on the fundamental principle of Faraday's law of electromagnetic induction. A single-turn current extraction coil with high bandwidth and zero insertion inductance is provided, and the signal processing circuit is set up. The signal processing circuit processes the matched voltage signal generated by the single-turn current extraction coil and the coil terminal matching resistor R_{d} to ultimately obtain the restored current. The single-turn copper coils within the single-turn current extraction coil have no iron core, so magnetic saturation does not occur, enabling direct measurement of very large currents.

In this embodiment, the high-bandwidth current-sensing extraction-coil sensor further includes an output current terminal, a measurement port Vₒᵤₜ₁ and a measurement port Vₒᵤₜ₂.

The output current terminal is connected to the signal processing circuit and the measurement port Vₒᵤₜ₂ respectively, and is used to output the restored current.

The measurement port Vₒᵤₜ₁ is connected to the single-turn current extraction coil, the coil terminal matching resistor R_{d}, and the signal processing circuit individually, and is used to perform frequency scanning on the single-turn current extraction coil to obtain a bandwidth of the single-turn current extraction coil.

The measurement port Vₒᵤₜ₂ is connected to the signal processing circuit and is used to perform frequency scanning on the high-bandwidth current-sensing extraction-coil sensor to obtain a bandwidth of the high-bandwidth current-sensing extraction-coil sensor.

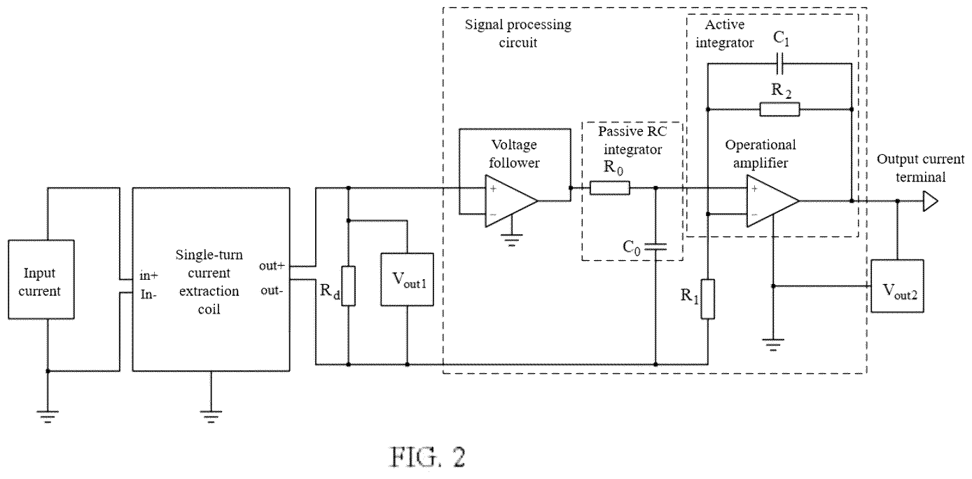

FIG. 2 illustrates a first schematic equivalent circuit diagram of the high-bandwidth current-sensing extraction-coil sensor. In this embodiment, the signal processing circuit includes a voltage follower, a passive RC integrator, a resistor R₁ and an active integrator.

A non-inverting input of the voltage follower is individually connected to an end of the coil terminal matching resistor R_{d}, an end of the measurement port Vₒᵤₜ₁, and the single-turn current extraction coil. An inverting input of the voltage follower is connected to the passive RC integrator. An output terminal of the voltage follower is connected to the passive RC integrator. The voltage follower is used to follow the matched voltage signal and output a followed voltage signal.

The passive RC integrator is individually connected to an end of the resistor R₁, the other end of the coil terminal matching resistor R_{d}, the other end of the measurement port Vₒᵤₜ₁, the single-turn current extraction coil, and the active integrator. The passive RC integrator is used to filter and integrate the following voltage signal sequentially, and output an integrated current signal.

The active integrator is individually connected to the other end of the resistor R₁, the measurement port Vₒᵤₜ₂, and the output current terminal. The active integrator is used to restore the integrated current signal and output the restored current to realize the current detection.

The end of the resistor R₁ is individually connected to the other end of the measurement port Vₒᵤₜ₁, the other end of the coil terminal matching resistor R_{d}, and the single-turn current extraction coil.

The signal processing circuit includes the passive RC integrator and the active integrator. Interference resistance of the voltage signal is enhanced by the passive RC integrator and the active integrator, enabling ultra-high bandwidth current detection.

Specifically, during operation of the high-bandwidth current-sensing extraction-coil sensor. In space, the input current flows from the positive input (in+) to the negative input (in−) of the single-turn current extraction coil. At this time, the voltage is generated across the forward output terminal (out+) and the reverse output terminal (out−) of the single-turn current extraction coil according to Faraday's law of electromagnetic induction. The generated voltage is impedance-matched by the coil terminal matching resistor R_{d}. The matched voltage signal from the coil terminal matching resistor R_{d} is then fed into the voltage follower, which follows the matched voltage signal to generate a followed voltage signal. The followed voltage signal is filtered and integrated by the passive RC integrator to output an integrated current signal. The integrated current signal is then processed by the resistor R₁ and the active integrator to restore the current signal, and finally the restored current is obtained, thereby realizing the complete current detection.

The function of the voltage follower is to follow the matched voltage signal and produce the followed voltage signal. The voltage follower, characterized by high input impedance and low output impedance, isolates the voltage signal and prevents signal loss, thereby improving the loading capacity of the high-bandwidth current-sensing extraction-coil sensor.

In this embodiment, the passive RC integrator includes a resistor R₀ and a capacitor C₀.

An end of the resistor R₀ is individually connected to the output terminal of the voltage follower and the inverting input of the voltage follower; the other end of the resistor R₀ is connected to an end of the capacitor C₀ and the active integrator; the end of the capacitor C₀ is connected to the active integrator; and the other end of the capacitor C₀ is individually connected to the end of the resistor R₁, the other end of the coil terminal matching resistor R_{d}, the other end of the measurement port Vₒᵤₜ₁, and the single-turn current extraction coil.

Specifically, the followed voltage signal is filtered and integrated sequentially through the resistor R₀ and the capacitor C₀, and the integrated current signal is output.

In this embodiment, the active integrator includes an operational amplifier, a resistor R₂ and a capacitor C₁.

A non-inverting input of the operational amplifier is individually connected to the other end of the resistor R₀ and the end of the capacitor C₀; an inverting input of the operational amplifier is individually connected to the other end of the resistor R₁, an end of the resistor R₂, and an end of the capacitor C₁; an output terminal of the operational amplifier is individually connected to the other end of the resistor R₂, the other end of the capacitor C₁, an end of the measurement port Vₒᵤₜ₂, and the output current terminal; the end of the resistor R₂ is individually connected to the end of the capacitor C₁ and the other end of the resistor R₁; the other end of the resistor R₂ is respectively connected to the other end of the capacitor C₁, the output current terminal, and the end of the measurement port Vₒᵤₜ₂; the end of the capacitor C₁ is connected to the other end of the resistor R₁; and the other end of the capacitor C₁ is connected to the output current terminal and the end of the measurement port Vₒᵤₜ₂.

Specifically, the integrated current signal, after passing through the resistor R₁, is processed by the operational amplifier, the resistor R₂, and the capacitor C₁ to restore the current signal, and finally the restored current is obtained, thereby realizing the complete current detection.

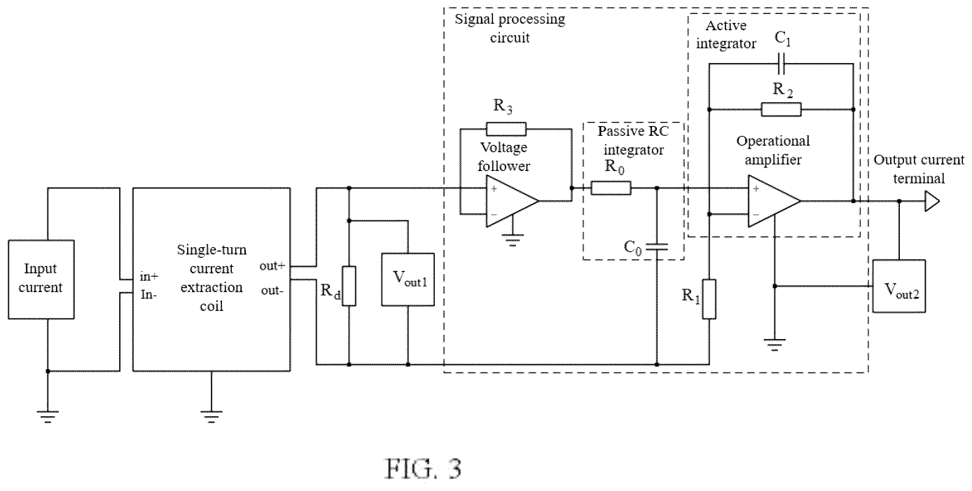

FIG. 3 illustrates a second schematic equivalent circuit diagram of the high-bandwidth current-sensing extraction-coil sensor. In this embodiment, the signal processing circuit further includes a resistor R₃.

An end of the resistor R₃ is connected to the inverting input of the voltage follower, and the other end of the resistor R₃ is individually connected to the output terminal of the voltage follower and the end of the resistor R₀.

Specifically, in the signal processing circuit including the voltage follower, the passive RC integrator, the resistor R₁, and the active integrator, the addition of the resistor R₃ makes the followed voltage signal more stable.

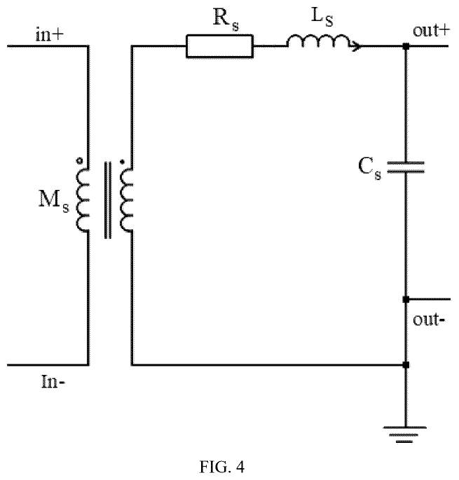

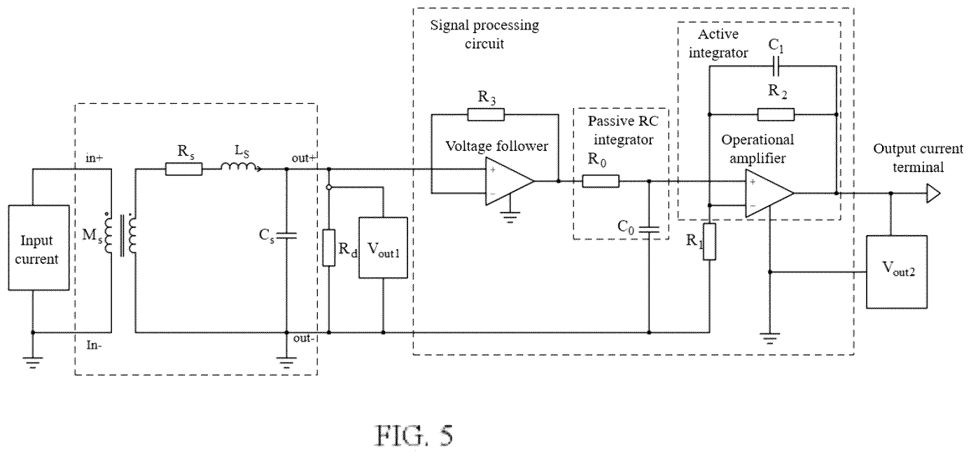

FIG. 4 illustrates a schematic equivalent circuit diagram of the single-turn current extraction coil. FIG. 5 illustrates a third schematic equivalent circuit diagram of the high-bandwidth current-sensing extraction-coil sensor. Referring to FIG. 4 and FIG. 5, in this embodiment, the equivalent circuit of the single-turn current extraction coil includes a mutual inductor Mₛ, a resistor Rₛ, a parasitic inductor L_{S} and a capacitor Cₛ arranged between the single-turn current extraction coil and a current-carrying conductor to be measured.

An end of the mutual inductor Mₛ is connected to an end of the resistor Rₛ, and the other end of the mutual inductor Mₛ is individually connected to an end of the capacitor Cₛ, the other end of the coil terminal matching resistor R_{d}, the other end of the measurement port Vₒᵤₜ₁, the other end of the capacitor C₀, and the end of the resistor R₁.

The other end of the resistor Rₛ is connected to an end of the parasitic inductor L_{S}, and the other end of the parasitic inductor L_{S} is respectively connected to the end of the capacitor Cₛ, the end of the coil terminal matching resistor R_{d}, the end of the measurement port Vₒᵤₜ₁, and the non-inverting input of the voltage follower, the other end of the capacitor Cₛ is individually connected to the end of the coil terminal matching resistor R_{d}, the end of the measurement port Vₒᵤₜ₁, and the non-inverting input of the voltage follower, and the end of the capacitor Cₛ is individually connected to the other end of the coil terminal matching resistor R_{d}, the other end of the measurement port Vₒᵤₜ₁, the other end of the capacitor C₀, and the end of the resistor R₁.

Specifically, the other end of the capacitor Cₛ and the other end of the mutual inductor Mₛ are both grounded.

The positive input (in+) and the negative input (in−) serve as inputs for the primary input current. The input current flows from the positive input (in+) of the single-turn current extraction coil through the mutual inductor Mₛ towards the negative input (in−), the resistor Rₛ, the parasitic inductor L_{S}, and the capacitor Cₛ, generating the voltage across the forward output terminal (out+) and the reverse output terminal (out−) of the single-turn current extraction coil.

Based on the formula

$${f}_{H} = \frac{1}{2 π} \cdot \sqrt{\frac{{R}_{s} + {R}_{d}}{{L}_{S} {C}_{s} {R}_{d}}} ,$$

the upper limit bandwidth f_{H} of the single-turn current extraction coil is calculated, typically R_{d}>>Rₛ, and the formula of the upper limit bandwidth of the single-turn current extraction coil can be simplified as

$${f}_{H} = \frac{1}{2 π} \cdot \sqrt{\frac{1}{{L}_{S} {C}_{s}}} .$$

Parameters such as parasitic inductance of the parasitic inductor L_{S} and capacitance of the capacitor Cₛ are extracted using a finite element parasitic parameter extraction tool. By applying the simplified formula for the upper limit bandwidth of the single-turn current extraction coil and the extracted values of parasitic inductance and capacitance, the upper limit bandwidth of the single-turn current extraction coil is determined. Based on the formula

$${f}_{L} = \frac{1}{2 π {R}_{0} {C}_{0}} ,$$

the lower limit bandwidth f_{L} of the single-turn current extraction coil can be obtained, and by adjusting R₀C₀=R₁C₁, a smooth transition between the passive integrator and the active integrator can be achieved.

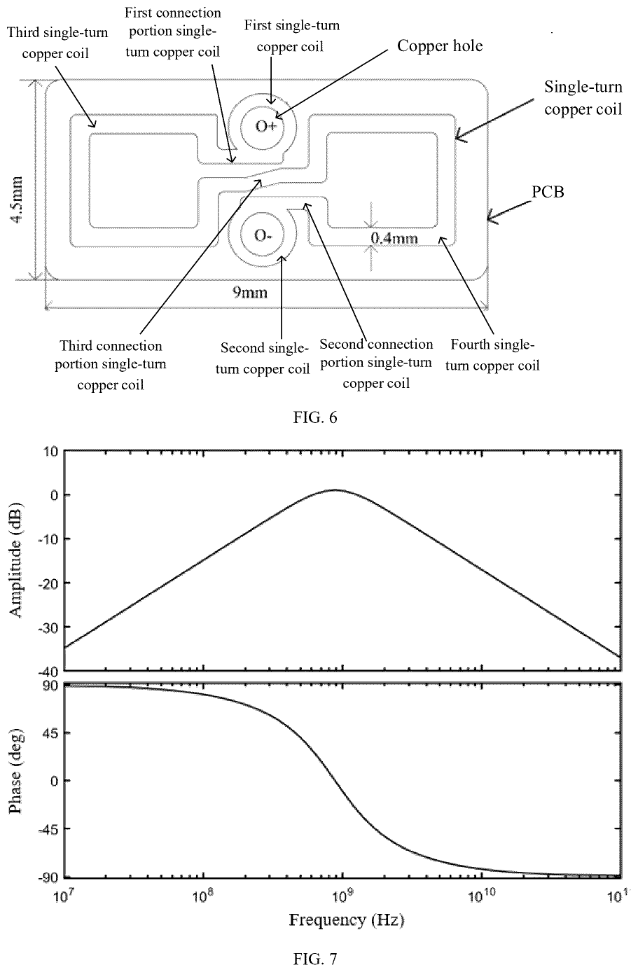

FIG. 6 illustrates a schematic structural diagram of the single-turn current extraction coil. In addition to the single-turn copper coils, the single-turn current extraction coil further includes a printed circuit board (PCB) and copper holes. The single-turn copper coils include a first single-turn copper coil, a second single-turn copper coil, a third single-turn copper coil, a fourth single-turn copper coil, a first connection portion single-turn copper coil, a second connection portion single-turn copper coil, and a third connection portion single-turn copper coil. Both the third single-turn copper coil and the fourth single-turn copper coil are square ring-shaped coils with openings.

The PCB is defined with two circular openings symmetrically arranged, and the first single-turn copper coil and the second single-turn copper coil are respectively arranged around the two circular openings.

The third single-turn copper coil is arranged on the PCB, and the third single-turn copper coil is located to a left side of the first single-turn copper coil, a lower surface of the first single-turn copper coil and an end of the opening of the third single-turn copper coil are located in a same horizontal plane, and the lower surface of the first single-turn copper coil and the end of the opening of the third single-turn copper coil are connected through the first connection portion single-turn copper coil.

The fourth single-turn copper coil is arranged on the PCB, and the fourth single-turn copper coil is located to a right side of the second single-turn copper coil, an upper surface of the second single-turn copper coil and an end of the opening of the fourth single-turn copper coil are located in a same horizontal plane, the upper surface of the second single-turn copper coil and the end of the opening of the fourth single-turn copper coil are connected through the second connection portion single-turn copper coil, and the third single-turn copper coil and the fourth single-turn copper coil are symmetrically arranged along a center.

The other end of the opening of the third single-turn copper coil and the other end of the opening of the fourth single-turn copper coil are connected through the third connection portion single-turn copper coil, and the third connection portion single-turn copper coil is located between the first single-turn copper coil and the second single-turn copper coil.

A length of the PCB is 9 milliliters (mm), a width of the PCB is 4.5 mm, diameters of the copper holes are both 0.9 mm, and ring widths of the third single-turn copper coil and the fourth single-turn copper coil are both 0.4 mm.

In space, the input current flows from the positive input (in+) of the single-turn current extraction coil to the negative input (in−) of the single-turn current extraction coil, generating a voltage across O+ and O−, i.e., out+ and out−, of the single-turn current extraction coil.

By adopting the single-turn copper coils of the single-turn current extraction coil achieves an impressive bandwidth of up to 884 megahertz (MHz).

The length of the PCB used for the single-turn current extraction coil is 9 mm, its width is 4.5 mm, and the line width, i.e., ring width, of the single-turn copper coil is 0.4 mm. Due to its compact size, the installation of the single-turn current extraction coil is facilitated, and both parasitic capacitance and parasitic inductance are kept low, thus improving the current detection bandwidth.

Using the PCB and components like the resistor, the capacitors, the operational amplifier, etc., for the signal integration circuit significantly reduces the cost of the high-bandwidth current-sensing extraction-coil sensor.

In this embodiment, a negative power supply terminal of the voltage follower is connected to ground.

In this embodiment, the end of the measurement port Vₒᵤₜ₂ and a negative power supply terminal of the operational amplifier are both connected to ground.

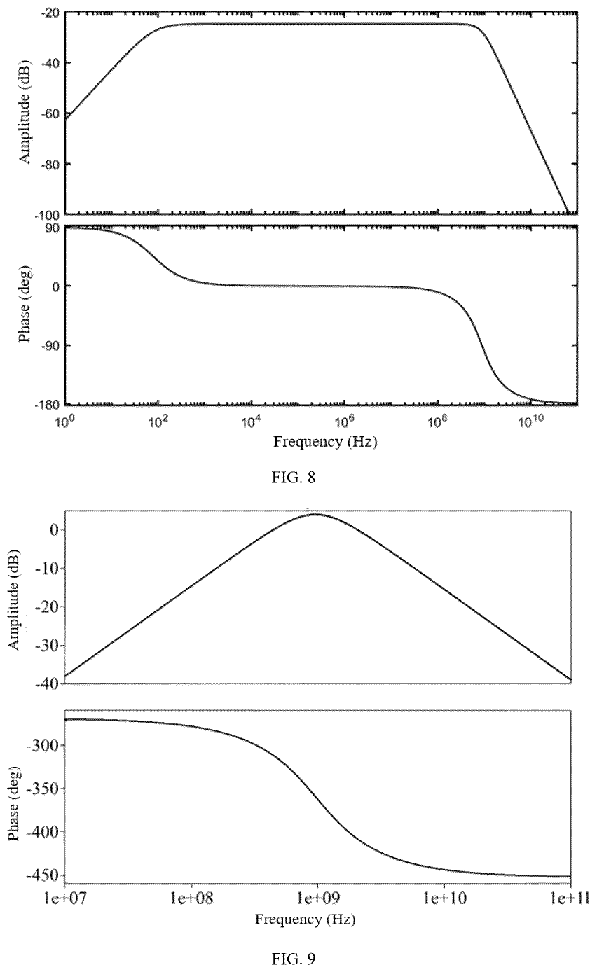

FIG. 7 illustrates a schematic theoretical analysis diagram of amplitude-frequency and phase-frequency response of the single-turn current extraction coil. FIG. 8 illustrates a schematic theoretical analysis diagram of amplitude-frequency and phase-frequency response of the high-bandwidth current-sensing extraction-coil sensor. Referring to FIG. 7 and FIG. 8, the single-turn current extraction coil is imported into the finite element parasitic parameter extraction tool, and parameters of the single-turn current extraction coil are extracted using the tool. These parameters include parasitic inductance of the parasitic inductor L_{S}, capacitance of the capacitor Cₛ, mutual inductance of the mutual inductor Mₛ, and resistance of the resistor Rₛ. The specific extracted parameter values are: the parasitic inductance of the parasitic inductor L_{S} is 9.4 nanohenries, the capacitance of the capacitor Cₛ is 3.5 picofarads, the resistance of the resistor Rₛ is 0.338 ohms, and the mutual inductance of the mutual inductor Mₛ is 0.29 nanohenries. Based on these extracted parameter values, theoretical analysis is performed using MATLAB software to obtain the amplitude-frequency and phase-frequency response of the single-turn current extraction coil. The upper graph in FIG. 7 shows the theoretical analysis curve of the amplitude-frequency response of the single-turn current extraction coil, with frequency on the horizontal axis and amplitude on the vertical axis. The lower graph in FIG. 7 shows the theoretical analysis curve of the phase-frequency response of the single-turn current extraction coil, with frequency on the horizontal axis and phase on the vertical axis. It can be seen that the upper limit bandwidth of the single-turn current extraction coil reaches as high as 884 MHz, which is three times the detection bandwidth compared to traditional sensors. Referring to FIG. 8, through the integration parameters of the passive RC integrator and active integrator, namely the resistor R₀, the capacitor C₀, the capacitor C₁, and the resistor R₂, theoretical analysis is performed using MATLAB software to obtain the amplitude-frequency and phase-frequency response of the high-bandwidth current-sensing extraction-coil sensor. The upper graph in FIG. 8 shows the theoretical analysis curve of the amplitude-frequency response of the sensor, with frequency on the horizontal axis and amplitude on the vertical axis. The lower graph in FIG. 8 shows the theoretical analysis curve of the phase-frequency response of the sensor, with frequency on the horizontal axis and phase on the vertical axis. It can be observed that the amplitude-frequency response remains stable within the range of 79 Hz to 884 MHz. Therefore, the high-bandwidth current-sensing extraction-coil sensor of the disclosure is capable of achieving current detection over an ultra-wide bandwidth range of 79 Hz to 884 MHz.

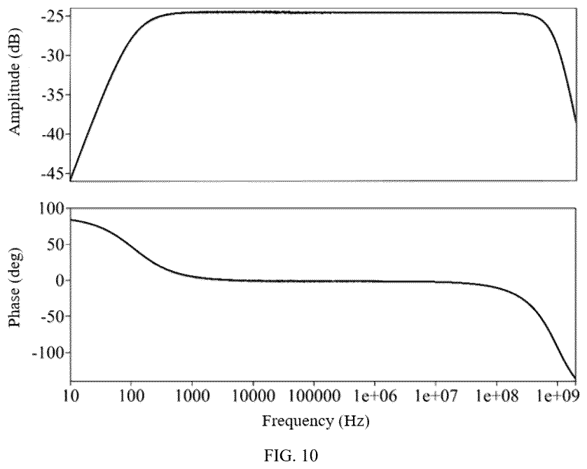

FIG. 9 illustrates a schematic simulation analysis diagram of the amplitude-frequency and phase-frequency response of the single-turn current extraction coil. FIG. 10 illustrates a schematic simulation analysis diagram of the amplitude-frequency and phase-frequency response of the high-bandwidth current-sensing extraction-coil sensor. Based on the theoretical analysis in FIG. 7 and FIG. 8, frequency scanning of the high-bandwidth current-sensing extraction-coil sensor of the disclosure is performed using circuit simulation software, and the simulation results are shown in FIG. 9 and FIG. 10. The upper graph in FIG. 9 shows the simulation analysis curve of the amplitude-frequency response of the single-turn current extraction coil, with frequency on the horizontal axis and amplitude on the vertical axis. The lower graph in FIG. 9 shows the simulation analysis curve of the phase-frequency response of the single-turn current extraction coil, with frequency on the horizontal axis and phase on the vertical axis. The upper graph in FIG. 10 shows the simulation analysis curve of the amplitude-frequency response of the high-bandwidth current-sensing extraction-coil sensor, with frequency on the horizontal axis and amplitude on the vertical axis. The lower graph in FIG. 10 shows the simulation analysis curve of the phase-frequency response of the sensor, with frequency on the horizontal axis and phase on the vertical axis. By comparing FIG. 7 and FIG. 8 with FIG. 9 and FIG. 10, it can be seen that the theoretical analysis of the amplitude-frequency and phase-frequency response of the single-turn current extraction coil in FIG. 7 matches the simulation analysis of the amplitude-frequency and phase-frequency response of the single-turn current extraction coil in FIG. 9. Similarly, the theoretical analysis of the amplitude-frequency and phase-frequency response of the high-bandwidth current-sensing extraction-coil sensor in FIG. 8 matches the simulation analysis of the amplitude-frequency and phase-frequency response of the high-bandwidth current-sensing extraction-coil sensor in FIG. 10. The theoretical and simulation analyses exhibit consistent trends in both amplitude-frequency and phase-frequency response curves. Therefore, the high-bandwidth current-sensing extraction-coil sensor of the disclosure is capable of achieving current detection over an ultra-wide bandwidth range of 79 Hz to 884 MHz, demonstrating its capability to detect currents in fast GaN devices.

The high-bandwidth current-sensing extraction-coil sensor of this embodiment of the disclosure includes the single-turn current extraction coil, the coil terminal matching resistor Ra and the signal processing circuit. The single-turn current extraction coil is used to generate the voltage based on the input current by using the Faraday's law, and the single-turn current extraction coil includes single-turn copper coils. The coil terminal matching resistor R_{d} is connected to the single-turn current extraction coil and is used to perform impedance matching on the voltage to produce the matched voltage signal. The signal processing circuit is individually connected to the single-turn current extraction coil and the coil terminal matching resistor R_{d} and is used to restore the matched voltage signal and output the restored current to achieve the current detection. In this situation, the single-turn copper coils of the single-turn current extraction coil are used to reduce parasitic capacitance and parasitic inductance, thereby increasing current detection bandwidth and avoiding introduction of parasitic inductance interference when measuring fast GaN devices. The single-turn current extraction coil, the coil terminal matching resistor R_{d} and the signal processing circuit are low in price, so that the manufacturing cost of the high-bandwidth current-sensing extraction-coil sensor is low.

Although specific embodiments of the disclosure have been described in detail through examples, those skilled in the art should understand that the above examples are provided for illustration purposes only and are not intended to limit the scope of the disclosure. Those skilled in the art should understand that modifications can be made to the above embodiments, or some technical features can be equivalently replaced, without departing from the scope and spirit of the disclosure. In particular, as long as there is no structural conflict, the various technical features mentioned in the different embodiments can be combined in any manner.

The above description represents only specific embodiments of the disclosure, but the protection scope of the disclosure is not limited to this. Any person skilled in the art, within the technical scope disclosed by the disclosure, could easily conceive of variations or substitutions, which should be covered within the protection scope of the disclosure. Therefore, the protection scope of the disclosure should be determined by the protection scope of the claims.

What is claimed is:

1. A high-bandwidth current-sensing extraction-coil sensor, comprising:
a single-turn current extraction coil, a coil terminal matching resistor R_{d}, and a signal processing circuit;
wherein the single-turn current extraction coil is configured to generate a voltage based on an input current by using Faraday's law, and the single-turn current extraction coil comprises single-turn copper coils;
the coil terminal matching resistor R_{d} is connected to the single-turn current extraction coil and is configured to perform impedance matching on the voltage to generate a matched voltage signal;
the signal processing circuit is connected to the single-turn current extraction coil and the coil terminal matching resistor R_{d} individually, and is configured to restore the matched voltage signal and output a restored current to realize current detection;
the single-turn current extraction coil further comprises a printed circuit board (PCB) and copper holes; the single-turn copper coils comprise a first single-turn copper coil, a second single-turn copper coil, a third single-turn copper coil, a fourth single-turn copper coil, a first connection portion single-turn copper coil, a second connection portion single-turn copper coil, and a third connection portion single-turn copper coil; and the third single-turn copper coil and the fourth single-turn copper coil are both square ring-shaped single-turn coils with openings;
the PCB is defined with two circular openings symmetrically arranged, and the first single-turn copper coil and the second single-turn copper coil are respectively arranged around the two circular openings;
the third single-turn copper coil is arranged on the PCB, and the third single-turn copper coil is located to a left side of the first single-turn copper coil, a lower surface of the first single-turn copper coil and an end of the opening of the third single-turn copper coil are located in a same horizontal plane, and the lower surface of the first single-turn copper coil and the end of the opening of the third single-turn copper coil are connected through the first connection portion single-turn copper coil;
the fourth single-turn copper coil is arranged on the PCB, and the fourth single-turn copper coil is located to a right side of the second single-turn copper coil, an upper surface of the second single-turn copper coil and an end of the opening of the fourth single-turn copper coil are located in a same horizontal plane, the upper surface of the second single-turn copper coil and the end of the opening of the fourth single-turn copper coil are connected through the second connection portion single-turn copper coil, and the third single-turn copper coil and the fourth single-turn copper coil are symmetrically arranged along a center;
another end of the opening of the third single-turn copper coil and another end of the opening of the fourth single-turn copper coil are connected through the third connection portion single-turn copper coil, and the third connection portion single-turn copper coil is located between the first single-turn copper coil and the second single-turn copper coil; and
a length of the PCB is 9 milliliters (mm), a width of the PCB is 4.5 mm, diameters of the copper holes are both 0.9 mm, and ring widths of the third single-turn copper coil and the fourth single-turn copper coil are both 0.4 mm.

2. The high-bandwidth current-sensing extraction-coil sensor as claimed in claim 1, wherein the high-bandwidth current-sensing extraction-coil sensor further comprises an output current terminal, a measurement port Vₒᵤₜ₁ and a measurement port Vₒᵤₜ₂;
the output current terminal is connected to the signal processing circuit and the measurement port Vₒᵤₜ₂ individually, and is configured to output the restored current;
the measurement port Vₒᵤₜ₁ is connected to the single-turn current extraction coil, the coil terminal matching resistor R_{d}, and the signal processing circuit individually, and is configured to perform frequency scanning on the single-turn current extraction coil to obtain a bandwidth of the single-turn current extraction coil; and
the measurement port Vₒᵤₜ₂ is connected to the signal processing circuit and is configured to perform frequency scanning on the high-bandwidth current-sensing extraction-coil sensor to obtain a bandwidth of the high-bandwidth current-sensing extraction-coil sensor.

3. The high-bandwidth current-sensing extraction-coil sensor as claimed in claim 2,
wherein the signal processing circuit comprises a voltage follower, a passive resistor-capacitor (RC) integrator, a resistor R₁ and an active integrator;
wherein a non-inverting input of the voltage follower is individually connected to an end of the coil terminal matching resistor R_{d}, an end of the measurement port Vₒᵤₜ₁, and the single-turn current extraction coil; an inverting input of the voltage follower is connected to the passive RC integrator; an output terminal of the voltage follower is connected to the passive RC integrator; and the voltage follower is configured to follow the matched voltage signal and output a followed voltage signal;
the passive RC integrator is individually connected to an end of the resistor R₁, another end of the coil terminal matching resistor R_{d}, another end of the measurement port Vₒᵤₜ₁, the single-turn current extraction coil, and the active integrator; and is configured to filter and integrate the following voltage signal sequentially, and output an integrated current signal;
the active integrator is individually connected to another end of the resistor R₁, the measurement port Vₒᵤₜ₂, and the output current terminal, and is configured to restore the integrated current signal and output the restored current to realize the current detection; and
the end of the resistor R₁ is individually connected to the another end of the measurement port Vₒᵤₜ₁, the another end of the coil terminal matching resistor R_{d}, and the single-turn current extraction coil.

4. The high-bandwidth current-sensing extraction-coil sensor as claimed in claim 3, wherein the passive RC integrator comprises a resistor R₀ and a capacitor C₀;
an end of the resistor R₀ is individually connected to the output terminal of the voltage follower and the inverting input of the voltage follower; another end of the resistor R₀ is connected to an end of the capacitor C₀ and the active integrator; the end of the capacitor C₀ is connected to the active integrator; and another end of the capacitor C₀ is individually connected to the end of the resistor R₁, the another end of the coil terminal matching resistor R_{d}, the another end of the measurement port Vₒᵤₜ₁, and the single-turn current extraction coil.

5. The high-bandwidth current-sensing extraction-coil sensor as claimed in claim 4, wherein the active integrator comprises an operational amplifier, a resistor R₂ and a capacitor C₁;
a non-inverting input of the operational amplifier is individually connected to the another end of the resistor R₀ and the end of the capacitor C₀; an inverting input of the operational amplifier is individually connected to the another end of the resistor R₁, an end of the resistor R₂, and an end of the capacitor C₁; an output terminal of the operational amplifier is individually connected to another end of the resistor R₂, another end of the capacitor C₁, an end of the measurement port Vₒᵤₜ₂, and the output current terminal; the end of the resistor R₂ is individually connected to the end of the capacitor C₁ and the another end of the resistor R₁; the another end of the resistor R₂ is individually connected to the another end of the capacitor C₁, the output current terminal, and the end of the measurement port Vₒᵤₜ₂; the end of the capacitor C₁ is connected to the another end of the resistor R₁; and the another end of the capacitor C₁ is connected to the output current terminal and the end of the measurement port Vₒᵤₜ₂.

6. The high-bandwidth current-sensing extraction-coil sensor as claimed in claim 4, wherein the signal processing circuit further comprises a resistor R₃;
an end of the resistor R₃ is connected to the inverting input of the voltage follower, and another end of the resistor R₃ is individually connected to the output terminal of the voltage follower and the end of the resistor R₀.

7. The high-bandwidth current-sensing extraction-coil sensor as claimed in claim 5, wherein an equivalent circuit of the single-turn current extraction coil comprises a mutual inductor Mₛ, a resistor Rₛ, a parasitic inductor L_{S} and a capacitor Cₛ arranged between the single-turn current extraction coil and a current-carrying conductor to be measured;
an end of the mutual inductor Mₛ is connected to an end of the resistor Rₛ, and another end of the mutual inductor Mₛ is individually connected to an end of the capacitor Cₛ, the another end of the coil terminal matching resistor R_{d}, the another end of the measurement port Vₒᵤₜ₁, the another end of the capacitor C₀, and the end of the resistor R₁;
another end of the resistor Rₛ is connected to an end of the parasitic inductor L_{S}, and another end of the parasitic inductor L_{S} is individually connected to another end of the capacitor Cₛ, the end of the coil terminal matching resistor R_{d}, the end of the measurement port Vₒᵤₜ₁, and the non-inverting input of the voltage follower, the another end of the capacitor Cₛ is individually connected to the end of the coil terminal matching resistor R_{d}, the end of the measurement port Vₒᵤₜ₁, and the non-inverting input of the voltage follower, and the end of the capacitor Cₛ is individually connected to the another end of the coil terminal matching resistor R_{d}, the another end of the measurement port Vₒᵤₜ₁, the another end of the capacitor C₀, and the end of the resistor R₁.

8. The high-bandwidth current-sensing extraction-coil sensor as claimed in claim 3, wherein a negative power supply terminal of the voltage follower is grounded.

9. The high-bandwidth current-sensing extraction-coil sensor as claimed in claim 5, wherein the end of the measurement port Vₒᵤₜ₂ and a negative power supply terminal of the operational amplifier are both grounded.

10. The high-bandwidth current-sensing extraction-coil sensor as claimed in claim 1, wherein a forward output terminal of the single-turn current extraction coil is connected to a current inflow terminal of a current-carrying conductor to be measured, and a negative output terminal of the single-turn current extraction coil is connected to a current output terminal of the current-carrying conductor to be measured.
